(19) United States
(12) Patent Application Publication
(10) Pub. No.: US 2024/0332315 A1
(43) Pub. Date: Oct. 3, 2024

(54) ARRAY SUBSTRATE AND DISPLAY PANEL

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Bo WU, Beijing (CN); Yin DENG, Beijing (CN); Xiongcan ZUO, Beijing (CN); Chengwei JI, Beijing (CN); Peng ZHOU, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/574,590

(22) PCT Filed: Apr. 29, 2022
(86) PCT No.: PCT/CN2022/090542

§ 371 Date: Dec. 27, 2023

(51) Int. Cl. H01L 27/12; G02F 1/1339; G02F 1/1362; G02F 1/1368; H01L 23/34

(52) U.S. Cl. CPC H01L 27/124; G02F 1/1339; G02F 1/136286; G02F 1/1368; H01L 23/345

(57) ABSTRACT

An array substrate and a display panel are provided. The array substrate includes a display region and a first peripheral region surrounding the display region, the array substrate includes: a base substrate; gate lines, located on the base substrate and extending along a first direction; data lines, located on the base substrate and extending along a second direction, the second direction and the first direction cross each other; pixel electrodes, arranged in an array along the first direction and the second direction respectively; heating line groups, at least partially arranged in the display region, each of the heating line groups includes a plurality of first heating lines, and the first heating lines in each of the heating line groups are connected with each other through connection lines at two ends of the each of the heating line groups, respectively.

### TECHNICAL FIELD

Embodiments of the present disclosure relate to an array substrate and a display panel.

### BACKGROUND

The liquid crystal display device controls a rotation of liquid crystal by applying an electric field to the liquid crystal, thereby controlling the modulation degree of the liquid crystal in a sub-pixel to display. In a special working environment, or in a special product or in a vehicle-mounted display device, it is required to adapt to a wide range of ambient temperature. For example, the low-temperature storage temperature of these display devices even reaches −45° C., while the low-temperature operation temperature even reaches −40° C. Because viscosity coefficient of liquid crystal material increases at low temperature, the threshold voltage will also increase, which will slow down the response speed and increase the response time, and the phenomenon of liquid crystal crystallization may occur, which may lead to that the liquid crystal display device cannot work normally. Therefore, in a special product or vehicle-mounted display device, measures should be taken to expand the low-temperature working range of the liquid crystal display device to ensure that they can work normally in the low-temperature environment.

### SUMMARY

Embodiments of the present disclosure relate to an array substrate and a display panel. In the array substrate, a plurality of heating lines in each of the heating line groups can share one or more conductive terminals, thereby reducing the number of conductive terminals used to apply power to the heating lines. The array substrates according to the embodiments of the present disclosure can solve the problems that the length of the crystalline film is too long, the cost is increased, the bending stress is increased, and there is a risk of light leakage.

According to some embodiments of the present disclosure, an array substrate is provided, the array substrate comprises a display region and a first peripheral region surrounding the display region, in which the array substrate comprises: a base substrate; a plurality of gate lines, located on the base substrate and extending along a first direction; a plurality of data lines, located on the base substrate and extending along a second direction, in which the second direction and the first direction cross each other; a plurality of pixel electrodes, arranged in an array along the first direction and the second direction respectively; a plurality of heating line groups, at least partially arranged in the display region, in which each of the plurality of heating line groups comprises a plurality of first heating lines arranged at intervals, and the plurality of first heating lines in each of the plurality of heating line groups are connected with each other through connection lines at two ends of the each of the plurality of heating line groups, respectively.

In the array substrate according to some embodiments of the present disclosure, the array substrate further comprises an annular region configured to arrange a frame sealant, the annular region is located between the first peripheral region and the display region, and the array substrate further comprises a second peripheral region located between the annular region and the display region.

In the array substrate according to some embodiments of the present disclosure, the plurality of heating line groups extend in a third direction and are arranged along a fourth direction crossing the third direction, one of the third direction and the fourth direction is parallel to the first direction, and the other of the third direction and the fourth direction is parallel to the second direction.

In the array substrate according to some embodiments of the present disclosure, the connection lines at first ends of every two adjacent ones of the plurality of heating line groups are electrically connected with each other, and the connection lines at second ends of every two adjacent ones of the plurality of heating line groups, which are electrically connected with each other, are respectively connected to different conductive terminals located in the first peripheral region.

In the array substrate according to some embodiments of the present disclosure, ends of the plurality of heating line groups extend to the second peripheral region.

In the array substrate according to some embodiments of the present disclosure, the connection lines at the second ends of the plurality of heating line groups are connected to the conductive terminals through fan-out lines.

In the array substrate according to some embodiments of the present disclosure, a width of each of the fan-out lines is greater than a width of each of first heating lines in the plurality of heating line groups.

In the array substrate according to some embodiments of the present disclosure, each of the heating line groups is connected with a plurality of conductive terminals, and a number of the first heating lines in each of the plurality of heating line groups is greater than a number of the conductive terminals connected with the each of the plurality of heating line groups.

In the array substrate according to some embodiments of the present disclosure, the third direction is parallel to the first direction, and multiple first heating lines in the plurality of heating line groups are arranged in at least one of following two positions: adjacent to corresponding gate lines, and a distance between an orthographic projection of a first heating line on the base substrate and an orthographic projection of a corresponding gate line on the base substrate is less than 6 microns; overlapping with middle parts of the plurality of pixel electrodes arranged in the first direction.

The array substrate according to some embodiments of the present disclosure, further comprises common electrodes corresponding to the plurality of pixel electrodes, in which pixel electrode and common electrode, which correspond to each other, are configured to apply an electric field, at least one of the pixel electrode and the common electrode, which correspond to each other, is provided with two groups of slits extending in different directions from each other to form a domain boundary line extending in the first direction at a joint of the two groups of slits, at least part of the first heating lines is overlapped with the middle parts of the plurality of pixel electrodes arranged in the first direction, so that the first heating lines overlap with domain boundary lines corresponding to the plurality of pixel electrodes arranged in the first direction.

The array substrate according to some embodiments of the present disclosure, further comprises common electrodes corresponding to the plurality of pixel electrodes, wherein pixel electrode and common electrode, which correspond to each other, are configured to apply an electric field, at least one of the pixel electrodes and the common electrode, which correspond to each other, is provided with slits, at least part of the first heating lines is arranged adjacent to the corresponding gate line and overlaps with an edge of the pixel electrode and/or an edge of the common electrode.

In the array substrate according to some embodiments of the present disclosure, at least part of the first heating lines is arranged adjacent to the corresponding gate line and overlaps with ends of the slits in the pixel electrode or the common electrode.

In the array substrate according to some embodiments of the present disclosure, the third direction is parallel to the second direction, multiple first heating lines in the plurality of heating line groups are arranged adjacent to corresponding data lines, and a distance between an orthographic projection of a first heating line on the base substrate and an orthographic projection of a corresponding data line on the base substrate is less than 6 microns.

The array substrate according to some embodiments of the present disclosure, further comprises a switching transistor arranged at a crossing position of the gate line and the data line, in which a first heating line is provided with a recess portion adjacent to the switching transistor, and an opening of the recess portion faces the switching transistor.

In the array substrate according to some embodiments of the present disclosure, the switching transistor connected to a data line adjacent to the first heating line is located at a side of the data line away from the first heating line.

In the array substrate according to some embodiments of the present disclosure, intervals between the plurality of first heating lines in each of the plurality of heating line groups are approximately equal, and an interval between adjacent first heating lines in each of the plurality of heating line groups is approximately the same as an interval between adjacent heating line groups.

In the array substrate according to some embodiments of the present disclosure, each of the plurality of heating line groups is U-shaped as a whole, and lengths of the plurality of heating line groups are different, so that the U-shaped heating line groups are sequentially nested.

In the array substrate according to some embodiments of the present disclosure, each first heating line in the plurality of heating line groups is U-shaped, and lengths of the first heating lines are different, so that the U-shaped first heating lines are sequentially nested, and an interval between adjacent first heating lines in each of the plurality of heating line groups is approximately the same as an interval between adjacent heating line groups.

In the array substrate according to some embodiments of the present disclosure, each of the plurality of heating line groups comprises a first part and a second part located on two sides of a center line of the display region, and extending directions of the center line, the first part and the second part are parallel to each other, and each of the plurality of heating line groups comprises a connection part connecting the first part and the second part, and an extending direction of the connection part is perpendicular to the extending direction of the center line.

In the array substrate according to some embodiments of the present disclosure, the connection lines at first ends and second ends of the plurality of heating line groups are respectively electrically connected to different conductive terminals located in the first peripheral region.

In the array substrate according to some embodiments of the present disclosure, the connection lines at first ends of the plurality of heating line groups are respectively electrically connected to different conductive terminals in the first peripheral region, and the connection lines at second ends of every two heating line groups in the plurality of heating line groups are electrically connected with each other.

In the array substrate according to some embodiments of the present disclosure, second parts of the plurality of heating line groups are arranged in sequence along a direction perpendicular to the extending direction of the center line, the second parts are located on two sides of a dividing line parallel to the center line, and the second parts located on one side of the dividing line are arranged in one-to-one correspondence with the second parts located on the other side of the dividing line, and the second parts located on two sides of the dividing line and corresponding to each other are symmetrical with respect to the dividing line in the direction perpendicular to the center line, and the connection lines of the corresponding second parts are electrically connected with each other.

The array substrate according to some embodiments of the present disclosure, further comprises a second heating line located in the second peripheral region, in which the second heating line comprises a plurality of second heating lines sequentially arranged from the display region toward the first peripheral region.

In the array substrate according to some embodiments of the present disclosure, a line density of the plurality of second heating lines at a position close to the display region is smaller than a line density of the second heating lines at a position close to the first peripheral region.

In the array substrate according to some embodiments of the present disclosure, a line density of the plurality of second heating lines located in the second peripheral region is greater than a line density of the first heating lines located in the display region.

In the array substrate according to some embodiments of the present disclosure, the second heating line comprises a plurality of second heating lines, and two ends of at least a part of adjacent second heating lines in the plurality of second heating lines are respectively electrically connected with each other.

The array substrate according to some embodiments of the present disclosure, further comprises a second heating line located in the second peripheral region, wherein the second heating line comprises a plurality of second heating lines arranged in sequence from the display region toward the first peripheral region, each of the second heating lines is U-shaped to surround a plurality of lateral edges of the display region, and a U-shaped opening of each of the second heating lines faces a region where the conductive terminals are arranged.

The array substrate according to some embodiments of the present disclosure, further comprises a second heating line located in the second peripheral region, wherein the second heating line is located at two sides of the display region in the fourth direction, and an extending direction of the second heating line is parallel to the third direction.

The array substrate according to some embodiments of the present disclosure, further comprises a second heating line located in the second peripheral region, wherein the second heating line comprises a plurality of second heating lines sequentially arranged from the display region toward the first peripheral region, each of the plurality of second heating lines is U-shaped to surround a plurality of lateral edges of the display region, and a U-shaped opening of each of the second heating lines has the same orientation as that of the U-shaped opening of each of the heating line groups.

In the array substrate according to some embodiments of the present disclosure, the plurality of heating line groups are respectively connected to heating conductive terminals located in the first peripheral region through a plurality of fan-out lines, and each of the plurality of fan-out lines comprises a bending structure, and lengths of the bending structures of at least two fan-out lines are different, so as to adjust a total length of each of the plurality of fan-out lines.

In the array substrate according to some embodiments of the present disclosure, the display region is in a shape of a rectangular, and the array substrate further comprises a gate line lead-out line and a data line lead-out line, in which the gate line is connected to a gate driving conductive terminal located in the first peripheral region through the gate line lead-out line, and the data line is connected to a data driving conductive terminal located in the first peripheral region through the data lead-out line, and the gate driving conductive terminal and the data driving conductive terminal are located at a first side of the display region, and the heating conductive terminal is located at a second side of the display region.

In the array substrate according to some embodiments of the present disclosure, an edge length at the first side of the display region is longer than an edge length at the second side of the display region.

In the array substrate according to some embodiments of the present disclosure, a line density of the plurality of second heating lines located at the first side of the display region is smaller than a line density of the plurality of second heating lines located at a side of the display region opposite to the second side, and the line density of the plurality of second heating lines located at the side of the display region opposite to the second side is smaller than a line density of the plurality of second heating lines located at a side of the display region opposite to the first side.

In the array substrate according to some embodiments of the present disclosure, the first side of the display region and the second side of the display region are opposite to each other.

The array substrate according to some embodiments of the present disclosure, further comprises a dummy heating line located between the second heating line and the display region.

In the array substrate according to some embodiments of the present disclosure, the dummy heating line comprises a U-shaped line located at a side of the display region, and the array substrate further comprises a temperature detection line located inside the U-shaped line.

In the array substrate according to some embodiments of the present disclosure, the dummy heating line comprises a U-shaped line around a plurality of lateral sides of the display region, and the array substrate further comprises a temperature detection line located between the U-shaped line and the display region.

In the array substrate according to some embodiments of the present disclosure, a material of the heating lines in the plurality of heating line groups comprises metal.

In the array substrate according to some embodiments of the present disclosure, the gate lines, the data lines and the heating lines are respectively located in different layers.

According to some embodiments of the present disclosure, a display panel is provided, and the display panel comprises any one of the array substrates according to the embodiments mentioned above; a color film substrate, arranged opposite to the array substrate; a frame sealant, arranged between the array substrate and the color film substrate and between the display region and the first peripheral region of the array substrate; and a liquid crystal layer, located between the array substrate and the color film substrate and in a region surrounded by the frame sealant.

In the display panel according to some embodiments of the present disclosure, the color film substrate comprises a plurality of color filters arranged in an array, the plurality of color filters are respectively arranged opposite to the plurality of pixel electrodes, and a black matrix is arranged among the plurality of color filters.

In the display panel according to some embodiments of the present disclosure, positions of the first heating lines in the display region comprise at least one of the following two positions: the first heating lines are arranged adjacent to corresponding gate lines, and orthographic projections of the first heating lines on the array substrate fall within an orthographic projection of the black matrix on the array substrate; the first heating lines are arranged adjacent to corresponding data lines, and the orthographic projections of the first heating lines on the array substrate fall within an orthographic projection of the black matrix on the array substrate.

The display panel according to some embodiments of the present disclosure, further comprises a flexible printed circuit board, in which the plurality of heating line groups are electrically connected with the flexible printed circuit board through conductive terminals located on the array substrate.

In the display panel according to some embodiments of the present disclosure, the flexible printed circuit board comprises a plurality of power line groups connected with the conductive terminals, and each of the plurality of power line groups comprises two power lines configured to apply different voltages.

In the display panel according to some embodiments of the present disclosure, the plurality of heating line groups are divided into a plurality of heating line sections, heating line groups electrically connected with each other are located in the same one of the plurality of heating line sections, and conductive terminals connected to the heating line groups in different ones of the plurality of heating line sections are connected to different ones of the plurality of power line groups.

In the display panel according to some embodiments of the present disclosure, a number of the plurality of heating line sections is the same as a number of the plurality of power line groups, and the plurality of power line groups are configured to be independently controlled to apply different voltages or different currents to different ones of the plurality of heating line sections.

In the display panel according to some embodiments of the present disclosure, the array substrate further comprises an annular region configured to arrange a frame sealant, the annular region is located between the first peripheral region and the display region, and the array substrate further comprises a second peripheral region located between the annular region and the display region, and the array substrate further comprises a second heating line located in the second peripheral region, and the second heating line comprises a plurality of heating lines extending from the display region towards the first peripheral region.

In the display panel according to some embodiments of the present disclosure, the first heating lines and the second heating lines are configured such that a heating power per unit area of the second heating lines located in the second peripheral region is greater than a heating power per unit area of the first heating lines located in the display region.

The display panel according to some embodiments of the present disclosure, further comprises a driver chip arranged at a first side of the display region.

In the display panel according to some embodiments of the present disclosure, the first heating lines located in the display region are configured to generate a first heating power per unit area, the second heating lines located in the second peripheral region at the first side of the display region are configured to generate a second heating power per unit area, and the second heating lines located in the second peripheral region at a side of the display region adjacent to the first side are configured to generate a third heating power per unit area, the second heating lines located in the second peripheral region at a side of the display region opposite to the first side are configured to generate a fourth heating power per unit area, the second heating power per unit area is greater than the first heating power per unit area, the third heating power per unit area is greater than or equal to the fourth heating power per unit area, and the fourth heating power per unit area is greater than or equal to the third heating power per unit area.

In the display panel according to some embodiments of the present disclosure, the second heating power per unit area is 2 to 10 times that of the first heating power per unit area, the third heating power per unit area is 3 to 12 times that of the first heating power per unit area, and the fourth heating power per unit area is 4 to 14 times that of the first heating power per unit area.

### BRIEF DESCRIPTION OF DRAWINGS

In order to more clearly explain the technical solution of the embodiments of the present disclosure, the following will briefly introduce the drawings of the embodiments. Obviously, the drawings in the following description only relate to some embodiments of the present disclosure, but not limit the present disclosure.

FIG. 1 is diagram illustrating a heating line arrangement scheme of an array substrate according to some embodiments of the present disclosure.

FIG. 2 is a schematic diagram of a connection mode of a heating line and a flexible printed circuit board for power supply according to the embodiment of FIG. 1.

FIG. 3 is a diagram illustrating a heating line arrangement scheme of an array substrate according to some embodiments of the present disclosure.

FIG. 4 is a diagram illustrating a heating line arrangement scheme of an array substrate according to some embodiments of the present disclosure.

FIG. 5 is a diagram illustrating a heating line arrangement scheme of an array substrate according to some embodiments of the present disclosure.

FIG. 6 is a schematic diagram of a connection mode of a heating line and a flexible printed circuit board for power supply according to the embodiment of FIG. 5.

FIG. 7 is a schematic diagram of another connection mode of a heating line and a flexible printed circuit board for power supply according to the embodiment of FIG. 5.

FIG. 8 is a schematic plan view of an array substrate according to some embodiments of the present disclosure.

FIG. 9 is a schematic plan view of an array substrate according to some embodiments of the present disclosure.

FIG. 10 is a schematic plan view of an array substrate according to some embodiments of the present disclosure.

FIG. 11 is a schematic plan view of an array substrate according to some embodiments of the present disclosure.

FIG. 12 is a schematic plan view of an array substrate according to some embodiments of the present disclosure.

FIG. 13 is a schematic plan view of an array substrate according to some embodiments of the present disclosure.

FIG. 14 is a schematic plan view of an array substrate according to some embodiments of the present disclosure.

FIG. 15 is a schematic diagram of an arrangement mode of heating lines in an array substrate according to some embodiments of the present disclosure.

FIG. 16 is a schematic diagram of an arrangement mode of heating lines in an array substrate according to some embodiments of the present disclosure.

FIG. 17 is a schematic plan view of an array substrate according to some embodiments of the present disclosure.

FIG. 18 shows a partially enlarged schematic view at three positions of FIG. 17.

FIG. 19 shows another arrangement mode of heating lines in a second peripheral region of the array substrate.

FIG. 20 is a schematic plan diagram of fan-out lines connecting heating lines and conductive terminals.

FIG. 21 shows a schematic diagram of a dummy heating line and a temperature detection line in an array substrate according to some embodiments of the present disclosure.

FIG. 22 shows a schematic diagram of a dummy heating line and a temperature detection line in an array substrate according to some embodiments of the present disclosure.

FIG. 23 illustrates a partial cross-sectional view of a display panel according to some embodiments of the present disclosure.

### DETAILED DESCRIPTION

In order to make objects, technical details and advantages of embodiments of the present disclosure clear, the technical solutions of the embodiments will be described in a clearly and fully understandable way in connection with the related drawings. It is apparent that the described embodiments are just a part but not all the embodiments of the present disclosure. Based on the described embodiments herein, those skilled in the art can obtain, without any inventive work, other embodiment(s) which should be within the scope of the present disclosure.

Unless otherwise defined, technical terms or scientific terms used herein shall have their ordinary meanings as understood by people with ordinary skills in the field to which this invention belongs. The words “first”, “second” and similar words used in the specification and claims of the patent application of the present disclosure do not indicate any order, quantity or importance, but are only used to distinguish different components. Similarly, similar words such as “a” or “an” do not refer to quantity limitation, but refer to that there is at least one.

In a special working environment, or in a special product or vehicle-mounted display device, it is required to adapt to a wide range of ambient temperatures. For example, the low-temperature storage temperature of these display devices even reaches −45° C., while the low-temperature operation temperature even reaches −40° C. Because the viscosity coefficient of liquid crystal material increases at low temperature, the threshold voltage will also increase, which will slow down the response speed and increase the response time, and the phenomenon of liquid crystal crystallization may occur, which may lead to that the liquid crystal display device cannot work normally. Therefore, in a special product or a vehicle-mounted display device, measures should be taken to expand the low-temperature working range of the liquid crystal display devices to ensure that they can work normally in the low-temperature environment.

In order to ensure that the liquid crystal display device operates at an appropriate temperature, one technology is to provide heating lines inside a cell of the liquid crystal display panel (between the upper substrate and the lower substrate of the panel which are opposite to each other), and heat the liquid crystal display panel by applying an electric power to the heating line. In this technology, the heating line adopts a single U-shaped line design, that is, two main branches of each single U-shaped line are single lines, two ends of the two main branches at one side are connected, and the other two ends of the two main branches at the other side form an opening. The single U-shaped line passes through an active display region (AA region) of the liquid crystal display panel, and a plurality of single U-shaped lines are arranged along a direction perpendicular to the direction in which the two main branches of the U-shaped line extend. A distance between the two branches of the U-shaped line is a pixel pitch, two ends of the single U-shaped line are respectively connected to the conductive terminals of a flip-chip film, and an external flexible printed circuit board (FPC) is connected to the flip-chip film to provide voltage or current for heating. The conductive terminals of the flip-chip film with the same voltage are connected together by jumpers on FPC, which can provide multiple groups of different high voltage and low voltage to realize the heating adjustment of the screen edge and the AA region. In the case where the high voltage and the low voltage are alternately applied to adjacent conductive terminals, the number of conductive terminals of the flip-chip film is strongly related to the resolution. Because the adjacent conductive terminals are alternately applied with the high voltage and the low voltage, the number of conductive terminals cannot be reduced. Taking the resolution of 1920×720 and the arrangement of heating lines parallel to the gate line as an example, there are 720 conductive terminals corresponding to the heating lines. This demand for a large number of conductive terminals leads to a long length of flip-chip film and increased cost; and the bending stress becomes larger, which has the risk of light leakage.

Some embodiments according to the present disclosure provide an array substrate, which includes a display region and a first peripheral region surrounding the display region. The array substrate includes: a base substrate; a plurality of gate lines located on the base substrate and extending along a first direction; a plurality of data lines located on the base substrate and extending along a second direction, the second direction and the first direction cross each other; a plurality of pixel electrodes arranged in an array along the first direction and the second direction respectively; a plurality of heating line groups at least partially arranged in the display region, each of the plurality of heating line groups includes a plurality of first heating lines arranged at intervals, and the plurality of first heating lines in each of the plurality of heating line groups are respectively connected with each other at two ends of the heating line group through connection lines. In the array substrate according to the embodiments of the present disclosure, because the heating lines are arranged in groups and two ends of the heating lines in each of the heating line groups are electrically connected with each other, the plurality of heating lines in each of the plurality of heating line groups can share one or more conductive terminals, thereby reducing the number of conductive terminals for applying power to the heating lines. The array substrate according to the embodiment of the present disclosure can solve the problems of long length of the flip-chip film, increased cost, increased bending stress and light leakage risk.

Hereinafter, the technical solutions according to some embodiments of the present disclosure will be described in more detail with reference to the accompanying drawings.

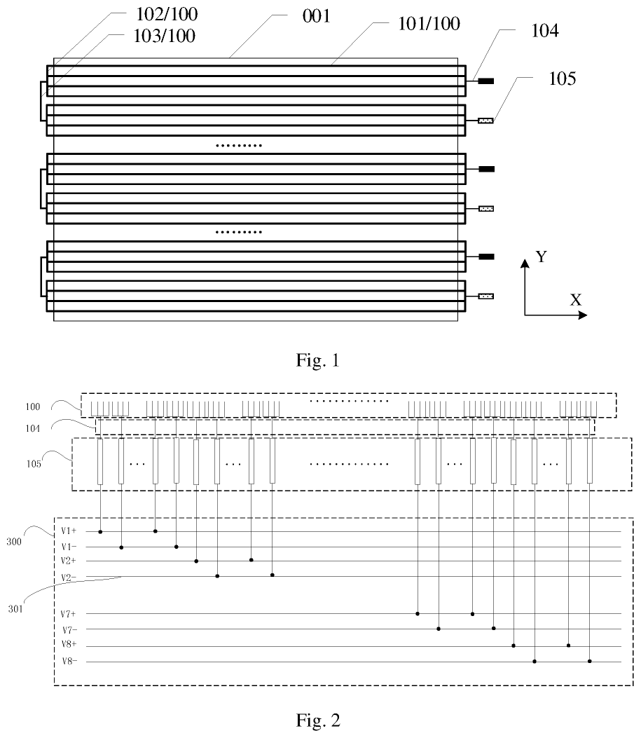

FIG. 1 is diagram illustrating a heating line arrangement scheme of an array substrate according to some embodiments of the present disclosure. As illustrated by FIG. 1, 001 represents an active display region (AA region) of the array substrate. A plurality of heating line groups 100 are arranged on the array substrate. Each of the heating line groups 100 includes four heating lines 101 extending in the X direction. For example, the X direction is consistent with the extending direction of the gate lines on the array substrate, that is, the heating line 101 extends in the direction parallel to the gate lines. The plurality of heating line groups 100 are arranged in the Y direction so as to substantially cover the entire AA region. A plurality of heating lines 101 in each of the heating line groups 100 are connected with each other at two ends (left end and right end in the figure) of the heating line group by first connection lines 102. For example, a plurality of heating lines 101 are connected by a first connection line 102 at the left end of the heating line group 100, and the plurality of heating lines 101 are connected by another first connection line 102 at the right end of the heating line 100. That is, the plurality of heating lines in each of the heating line groups 101 are connected in parallel. Therefore, in this case, the plurality of heating lines in each of the heating line groups 100 can share one or more conductive terminals, thereby reducing the number of conductive terminals.

It should be noted that although the plurality of first heating lines of the heating line group are respectively connected at two ends through first connection lines, the form of the first connection line is not particularly limited, for example, the first connection line may be a part of the first heating line, may be an independent part, or may be a part integrally formed with the plurality of first heating lines. As long as the ends of the plurality of first heating lines can be connected with each other, the first connection line can be in any suitable form.

As illustrated by FIG. 1, in the extending direction of the plurality of heating line groups 100, the heating line groups respectively extend to the outside of AA region and cross the AA region in X direction. However, the embodiments according to the present disclosure are not limited thereto. For example, the end of the heating line group 100 may be inside an edge of the AA region. In some examples, the plurality of heating lines 101 in each of the heating line groups 100 are arranged at the same interval, and the interval between heating lines 101 in each of the heating line groups 100 is equal to the interval between adjacent heating line groups 100, so that the plurality of heating lines 101 arranged at substantially equal distances can be arranged in the whole AA region to uniformly heat the AA region.

As illustrated by FIG. 1, at the left end of the heating lines, the first connection lines 102 of adjacent heating line groups 100 are electrically connected through a second connection line 103, thereby electrically connecting the adjacent heating line groups 100 at the left end. At the right end of the heating line groups 100 which are electrically connected with each other, each of the first connection lines 102 is connected with a conductive terminal 105 through a fan-out line 104. For example, a width of the fan-out line 104 may be larger than the width of each of the first heating lines 101 in the heating line group. The two conductive terminals 105 connected to the heating line groups 100, which are electrically connected with each other, are shown in black and white, respectively, which is only used to indicate that the two conductive terminals can apply different voltages, thereby applying voltages to the two heating line groups 100 as connected to heat the heating line groups. The black conductive terminals 105 and the white conductive terminals 105 do not represent structural differences. The conductive terminals 105 may be disposed in a peripheral region of the array substrate, for example, the peripheral region outside the area where the frame sealant is disposed on the array substrate. Some more specific examples of the conductive terminals 105 will be described in the following embodiments.

It should be noted that in this embodiment, the first connection lines of adjacent heating line groups 100 are electrically connected through the second connection line 103, which is only an example. For example, different first connection lines may be directly connected or integrally formed.

FIG. 2 is a schematic diagram of a connection mode of a heating line and a flexible printed circuit board (FPC) for power supply according to the embodiment of FIG. 1. It should be noted that only partial structure of one end of the heating line group connected with the conductive terminal, but not the whole heating line group is shown in FIG. 2. In addition, for the convenience of illustration, the extending direction of the heating line here is not the same as that shown in FIG. 1. For example, each of the first connection lines (right ends in FIG. 1) at the ends of the plurality of heating line groups is connected to the conductive terminal 105 through a fan-out line 104. If a display panel with a resolution of 1920×720 is taken as an example, in the case where heating lines are arranged along each of the gate lines, 720 heating lines 101 can be provided. Every four heating lines 101 are connected as one heating line group, and each of the heating line groups uses one conductive terminal, so the number of the conductive terminals can be reduced from 720 to 180, thereby reducing the length of flip-chip film with the conductive terminals.

The conductive terminals on the flip-chip film are electrically connected with the power lines in FPC respectively. In the example shown in FIG. 2, the FPC 300 provides eight groups of power lines, and each group of the power lines includes two power lines 301 which apply high voltage and low voltage respectively. For example, eight groups of power lines can respectively apply different high voltage and low voltage V1˜V8 to the heating lines. For example, the two power lines 301 representing V1+ and V1− belong to the same power line group, which are used to apply the high voltage and the low voltage respectively, so that a voltage difference is generated at two ends of the heating line group supplied by the power line group, so that the heating lines in the heating line group generate heat. The number of power line groups provided by FPC can be increased or decreased according to the heating situation in AA region, which is not particularly limited according to the embodiment of the present disclosure.

For example, the plurality of heating line groups 100 in the AA region may be divided into a plurality of heating line sections, and each of the heating line sections includes a plurality of heating line groups. A plurality of heating line groups in each of the heating line sections are connected to the same power line group. That is to say, the same voltage is applied to these heating line groups through the same power line group. The heating line groups in different heating line sections are connected to different power line groups, so different voltages can be applied to the heating line groups in different heating line sections. Therefore, the voltage applied to the heating lines in different regions can be adjusted according to the different temperatures in different regions on the array substrate, so that the heating power of the heating lines in different heating line sections is different, so as to compensate the temperature in different regions. It should be noted that the adjacent heating line groups, which are electrically connected with each other, are located in the same heating line section because the voltages are applied through the two conductive terminals respectively. For example, a plurality of power line groups are configured to be independently controlled to apply different voltages or currents to different heating line sections. For example, the number of the plurality of heating line sections is the same as that of the plurality of power line groups.

Although the above embodiments are described by taking the case where each of the heating line groups includes four heating lines as an example, the embodiments according to the present disclosure are not limited thereto. For example, the number of the heating lines in each of the heating line groups may be less than 4 or more than 4. For example, each of the heating line groups may include 8 heating lines. In this case, if a display panel with a resolution of 1920×720 is taken as an example, in the case where the heating lines are arranged along each of the gate lines, 720 heating lines 101 can be provided. Every eight heating lines 101 are connected as one heating line group, and each of the heating line groups uses one conductive terminal, so the number of the conductive terminals can be reduced from 720 to 90.

FIG. 3 is a diagram illustrating a heating line arrangement scheme of an array substrate according to some embodiments of the present disclosure. As illustrated by FIG. 3, similar to the embodiment shown in FIG. 1, 001 represents an active display region (AA region) of the array substrate. A plurality of heating line groups 100 are arranged on the array substrate. Different from the embodiment shown in FIG. 1, in this embodiment, each of the heating line groups 100 includes eight heating lines 101 extending in the Y direction. For example, the Y direction coincides with the extending direction of the data lines on the array substrate, that is, the heating line 101 extends along the direction of the data lines. The plurality of heating line groups 100 are arranged in the X direction so as to substantially cover the entire AA region. The plurality of heating lines 101 in each of the heating line groups 100 are connected with each other at two ends (upper end and lower end in the figure) of the heating line group by the first connection lines 102. For example, the plurality of heating lines 101 are connected by a first connection line 102 at the lower end of the heating line group 100, and the plurality of heating lines 101 are connected by another first connection line 102 at the upper end of the heating line 100. That is, the plurality of heating lines in each of the heating line groups 101 are connected in parallel. Therefore, in this case, the plurality of heating lines in each of the heating line groups 100 can share one or more conductive terminals, thereby reducing the number of the conductive terminals.

As illustrated by FIG. 3, in the extending direction of the plurality of heating line groups 100, the heating line groups respectively extend to the outside of the AA region and cross the AA region in the Y direction. However, the embodiments according to the present disclosure are not limited thereto. For example, the end of the heating line group 100 may be inside the edge of the AA region. In some examples, the plurality of heating lines 101 in each of the heating line groups 100 are arranged at the same interval, and the interval between the heating lines 101 in each of the heating line groups 100 is equal to the interval between adjacent heating line groups 100, so that the plurality of heating lines 101 arranged at substantially equal distances can be arranged in the whole AA region to heat the AA region.

As illustrated by FIG. 3, at the lower end of the heating line, the first connection lines 102 of adjacent heating line groups 100 are electrically connected through a second connection line 103, thereby electrically connecting the adjacent heating line groups 100 at the lower end. At the upper ends of the heating line groups 100 which are electrically connected with each other, each of the first connection lines 102 is connected with a conductive terminal 105 through a fan-out line 104.

The connection mode of the heating line and the flexible printed circuit board for power supply in the embodiment shown in FIG. 3 is similar to that shown in FIG. 2, and the description is not repeated here. The embodiment of FIG. 3 is different from that of FIG. 1 in terms of the number of heating lines in each of the heating line groups and the extending direction of the heating lines. If the heating line extends along the Y direction in the figure, the conductive terminal for connecting with the heating line may be arranged at a side of the display region in the Y direction to facilitate the connection with the heating line, but the embodiments according to the present disclosure are not limited thereto. Because the heating lines are arranged in the direction of the data lines in this embodiment, the number of the heating lines can be determined based on the number of data lines. For example, if a display panel with a resolution of 1920×720 is taken as an example, in the case where the heating lines are arranged along the data lines, and each column of pixels (each pixel can include multiple sub-pixels) is provided with one heating line, then 1920 heating lines 101 can be provided. Every eight heating lines 101 are connected as one heating line group, and each of the heating line groups uses one conductive terminal, so the number of conductive terminals can be reduced from 1920 to 240, thereby reducing the length of the flip-chip film with conductive terminals.

Other aspects of the embodiment shown in FIG. 3 can be described with reference to the embodiments shown in FIGS. 1 and 2. For example, the plurality of heating line groups in FIG. 3 can also be divided into a plurality of heating line sections to be respectively connected to different power line groups in flexible printed circuit board. The descriptions of repeated features will not be repeated here.

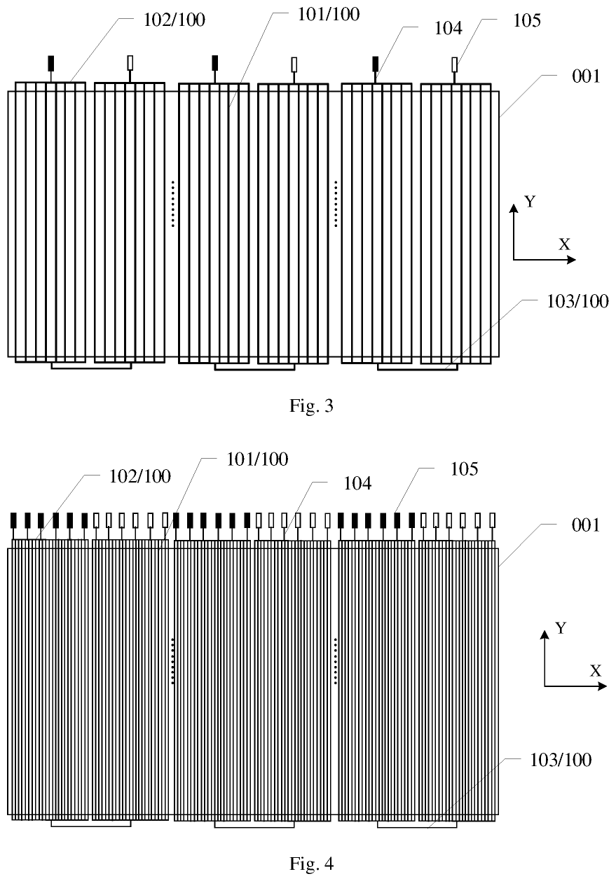

FIG. 4 is a diagram illustrating a heating line arrangement scheme of an array substrate according to some embodiments of the present disclosure. The embodiment shown in FIG. 4 also includes a plurality of heating line groups. Different from FIG. 3, the number of heating lines in each of the heating line groups in the embodiment of FIG. 4 is 24. In addition, the number of fan-out lines and the number of conductive terminals connected to each of the heating line groups are both greater than 1. For example, as illustrated by FIG. 4, the number of the fan-out lines connected to each of the heating line groups is 6, and the number of the conductive terminals connected to each of the heating line groups is also 6. In the case where the number of the heating lines in each of the heating line groups is relatively large, the current flowing through each of the heating line groups is relatively large during the heating process. Therefore, if each of the heating line groups still uses a fan-out line for power supply, the current of the fan-out line may be too large. In this embodiment, a plurality of fan-out lines and a plurality of conductive terminals are used for connection in each of the heating line groups, thus avoiding the situation that the current in a single fan-out line is too large.

In addition, in this embodiment, the number of heating lines in each of the heating line groups is 24, the number of the fan-out lines corresponding to each of the heating line groups is 6, and a ratio of the number of the heating lines to the number of the fan-out lines is 4. However, the ratio is not limited thereto. For example, the number of the heating lines and the number of the corresponding fan-out lines of each of the heating line groups can be 8, 6, 3, etc. In order to ensure heating efficiency and product stability, in some examples, the ratio can range from 2 to 10.

For the connection mode of the heating line and the flexible printed circuit board in the embodiment shown in FIG. 4, it can also refer to the descriptions in the embodiments shown in FIG. 1 and FIG. 2. However, it should be noted that the conductive terminals connected to the same heating line group should be connected to the same power line in the flexible printed circuit board.

For the embodiment shown in FIG. 4, the heating line also extends along the extending direction of the data line. For example, a heating line can be provided in each column of sub-pixels. For example, still taking the display panel with the resolution of 1920×720 as an example, in the case where the heating lines are arranged along the data lines and one heating line is set for each column of sub-pixels (each pixel can include three sub-pixels), then 1920×3 heating lines 101 can be provided, that is, 5760 heating lines can be provided. Every 24 heating lines 101 are connected as one heating line group, and each of the heating line groups uses 6 conductive terminals, so the number of conductive terminals is 1440. Therefore, compared with the scheme that each heating line is connected with one conductive terminal, the number of the conductive terminals can be reduced from 5760 to 1440, thus reducing the length of the flip-chip film with the conductive terminals.

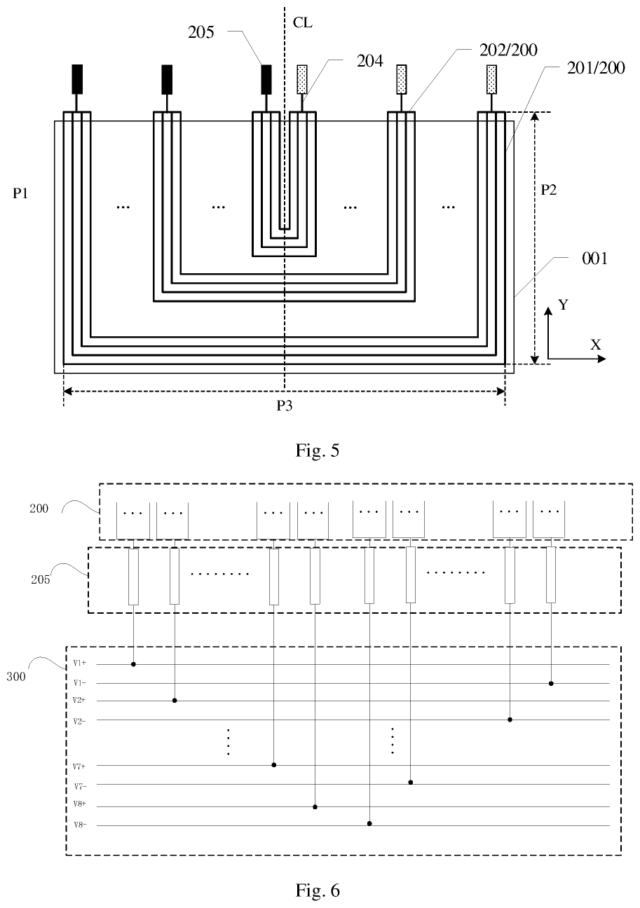

FIG. 5 is a diagram illustrating a heating line arrangement scheme of an array substrate according to some embodiments of the present disclosure. The embodiment of FIG. 5 includes a plurality of U-shaped heating line groups 200, and each of the U-shaped heating line groups 200 includes a plurality of U-shaped heating lines 201. The plurality of heating lines 201 in each of the U-shaped heating line groups 200 are connected with each other at two ends of the heating line group 200 by first connection lines 202. Two ends of each of the heating line groups are respectively connected to the conductive terminals 205 through the fan-out lines 204.

Different from the embodiments of FIG. 1, FIG. 2, FIG. 4 and FIG. 5, each of the heating line groups in FIG. 5 is generally U-shaped. The lengths of the plurality of heating line groups are different, so that the U-shaped structures of the plurality of heating line groups can be nested with each other. For example, FIG. 5 exemplarily shows an outermost U-shaped heating line group, an innermost U-shaped heating line group and an intermediate U-shaped heating line group between the outermost U-shaped heating line group and the innermost U-shaped heating line group. The innermost U-shaped heating line group has the smallest length, so it can be nested inside the middle heating line group; the length of the middle heating line group is smaller than that of the outermost heating line group, so it can be nested inside the outermost heating line group. By analogy, the plurality of heating line groups are nested with each other, so that the whole AA region can be basically covered to heat the AA region.

In addition, for each of the U-shaped heating line groups, each of the heating lines is also U-shaped. Similarly, the lengths of the heating lines are different, so that the plurality of U-shaped heating lines can be nested in turn.

In some examples, the interval in the X direction in each of the heating line groups is equal to the interval in the X direction in each of the heating line groups. The interval of each of the heating line groups in the Y direction is equal to the interval of each of the heating line groups in the Y direction. Because the U-shaped heating line group includes a part extending along the X direction and a part extending along the Y direction, the interval in the X direction refers to the interval between the parts of the U-shaped heating line group extending along the Y direction, and the interval in the Y direction refers to the interval between the parts of the U-shaped heating line groups extending along the X direction. Similarly, the interval in the X direction between multiple heating lines in each of the heating line groups refers to the interval between the parts of U-shaped heating lines extending in the Y direction, and the interval in the Y direction refers to the interval between the parts of U-shaped heating lines extending in the X direction.

As illustrated by FIG. 5, each of the heating line groups 200 includes a first part P1 and a second part P2 located on two sides of a center line CL in the Y direction of the display region. The first part P1 and the second part P2 also extend along the Y direction, parallel to the extending direction of the center line CL. In addition, each of the heating line groups 200 further includes a connection part P3 connecting the first part P1 and the second part P2. The extending direction of the connection part P3 is perpendicular to the extending direction of the center line CL, that is, the connection part P3 extends in the X direction.

As can be seen from FIG. 5, the conductive terminals connected to the two ends of each of the heating line groups can be connected to power lines with different potentials, so that the two power lines can apply voltage to the U-shaped heating line group to heat the heating line group. Hereinafter, the connection mode between the U-shaped heating line and the flexible printed circuit board will be described.

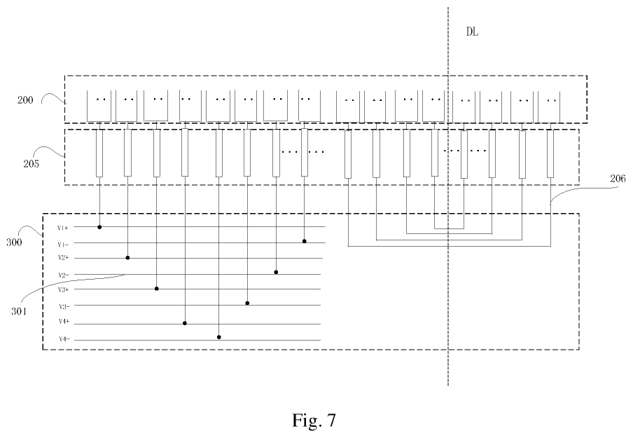

FIG. 6 is a schematic diagram of a connection mode between a heating line and a flexible printed circuit board (FPC) 300 for power supply according to the embodiment of FIG. 5. It should be noted that only partial structure of the ends connected with the conductive terminal of the heating line group, but not the whole heating line group is shown in FIG. 6. In addition, for the convenience of illustration, the orientation of the end of the heating line here is not consistent with the orientation of the end of the U-shaped heating line shown in FIG. 5. The connection mode of the U-shaped heating line group and the flexible printed circuit board in FIG. 6 is similar to that of the linear heating line group and the flexible printed circuit board in FIG. 2, but the connection sequence is slightly different. It should be noted that the two end parts of the U-shaped heating line group are located on two sides of the center line of AA region, so in the case where the U-shaped heating line group is connected with the power lines of FPC, it should be considered that the two symmetrical end parts on two sides of the center line are the ends of the same heating line group, so the two symmetrical end parts should be connected to the same set of power lines (two power lines applying high voltage and low voltage) in FPC. It should be noted that, except that two ends of the same U-shaped heating line group need to be connected with two power lines in the same power line group, the heating line group can also be divided into a plurality of heating line sections in a manner similar to that in FIG. 2, and each of the heating line sections can include a plurality of U-shaped heating line groups. The plurality of U-shaped heating line groups in each of the heating line sections can be connected to two power lines of the same power group. By grouping the heating lines and connecting them to different power line groups, the heating line groups in different areas can be controlled independently, so the temperature in different regions of the display panel can be adjusted, so that the temperature of the whole display panel is more balanced. For other aspects of connection with FPC, please refer to the descriptions of FIG. 2, which will not be repeated herein.

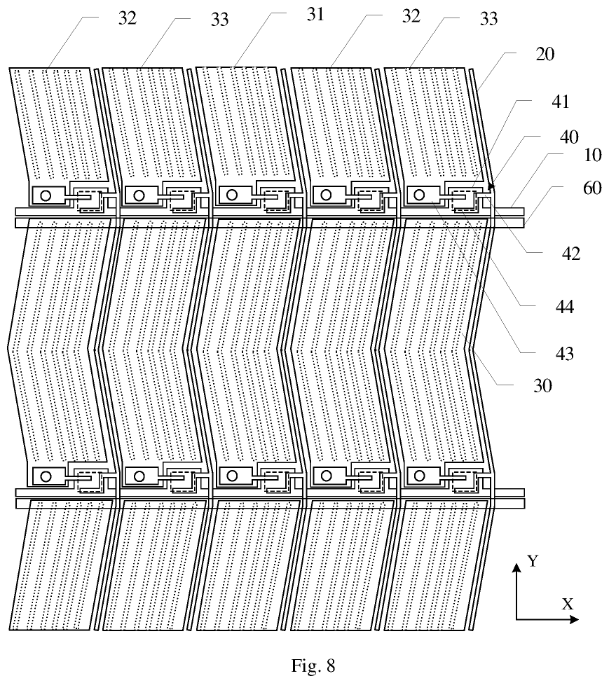

FIG. 7 shows a schematic diagram of another connection mode between a heating line and a flexible printed circuit board (FPC) 300 for power supply according to the embodiment of FIG. 5. As illustrated by FIG. 7, different from FIG. 6, the conductive terminals connected at the ends of the second parts (parts located at the right side in the figure) of the U-shaped heating line groups are connected in pairs. For example, the corresponding (connected) conductive terminals of two U-shaped heating lines can be electrically connected with each other through a third connection line 206. This connection is to electrically connect two U-shaped heating line groups with each other. After being electrically connected with each other, the ends of the first parts of the two U-shaped heating line groups are used to connect with the power line in FPC. For example, the ends of the first parts of the two U-shaped heating line groups that are electrically connected with each other are respectively connected with two power lines in the same power supply group, so that the two power lines supply power to the two U-shaped heating line groups to heat the U-shaped heating line groups. In addition, similarly, the U-shaped heating line groups can be divided to form a plurality of heating line sections, and each of the heating line sections includes a plurality of U-shaped heating line groups. In the case, two U-shaped heating line groups connected with each other should be divided into the same heating line section.

For example, as illustrated by FIG. 7, the second parts (parts located at the right side in the figure) of the plurality of U-shaped heating line groups are arranged in sequence along the direction perpendicular to the center line of AA region (see FIG. 6). The plurality of second parts are respectively located on two sides of the dividing line DL. The extending direction of the dividing line DL is parallel to the direction of the center line of the AA region. A plurality of second parts located on one side of the dividing line DL are arranged in one-to-one correspondence with a plurality of second parts located on the other side of the dividing line DL, and the positions of the second parts located on two sides of the dividing line DL corresponding to each other relative to the dividing line DL are in the direction perpendicular to the center line (or dividing line DL). For example, as illustrated by FIG. 7, the first one of the second parts located at the left side of the dividing line DL in the direction from right to left and the first one of the second parts located at the right side of the dividing line DL in the direction from left to right correspond to each other, which have equal distances from the dividing line DL in the lateral direction; a second one of the second parts located at the left side of the dividing line DL in the direction from right to left and a second one of the second parts located at the right side of the dividing line DL in the direction from left to right correspond to each other, which have equal distances from the dividing line DL in the lateral direction; a third one of the second parts located at the left side of the dividing line DL and in the direction from right to left and a third one of the second parts located at the right side of the dividing line DL in the direction from left to right correspond to each other, which have equal distances from the dividing line DL in the lateral direction; and so on. Therefore, the positions of the second parts corresponding to each other at two sides of the dividing line DL in the lateral direction are symmetrical to each other. It should be noted that the symmetry here does not require strict symmetry of the positions of the second parts corresponding to each other, as long as the approximate symmetrical positional relationship is satisfied. For example, as illustrated by FIG. 7, the conductive terminals corresponding to the two second parts, which correspond to each other, are electrically connected with each other. In this case, only the plurality of conductive terminals of the first parts need to be connected to the power lines. This connection of the second parts corresponding to each other can balance the length between the U-shaped heating line groups which are electrically connected. For example, the innermost U-shaped heating line group and the outermost heating line group among a plurality of U-shaped heating line groups are electrically connected with each other, while the innermost heating line group has the shortest length and the outermost heating line group has the longest length; a U-shaped heating line group located at the secondary inner side of the plurality of U-shaped heating line groups and a heating line group located at the secondary outer side of the plurality of U-shaped heating line groups are electrically connected with each other, and so on. Therefore, the lengths between the connected U-shaped heating line groups are relatively balanced, which makes the heating power of each of the heating line groups relatively uniform compared with the way that the two ends of each of the U-shaped heating line groups are connected to the power line applying high voltage and low voltage respectively in the previous embodiment.

Although FIG. 7 shows that the conductive terminals of the second parts corresponding to each other are connected with each other after the second parts are connected to the conductive terminals in the embodiment. However, the embodiments according to the present disclosure are not limited thereto, and the first connection lines of the second parts may be directly electrically connected through the third connection line 206, so that the conductive terminals for the connection of the second parts are no longer needed, and the fan-out lines corresponding to this part for the connection may also be omitted. The connection mode of this embodiment can be understood with reference to FIG. 7, so the corresponding illustration here is omitted for convenience and conciseness.

It should be noted that the number of the heating lines in each of the heating line groups in the above embodiment is exemplary, and the number of the conductive terminals can be reduced as long as multiple heating lines are connected with each other. The number of specific heating lines in each of the heating line groups can be adjusted according to the actual size of the panel product, the expected ambient temperature, the predetermined heating power range, the resolution of the display panel and other factors.

The above U-shaped heating line groups only shows that the openings face in one direction along the Y direction. In this case, both the first part and the second part of the U-shaped heating line group extend along the Y direction and the third part extends along the X direction. However, the embodiments according to the present disclosure are not limited thereto, and the openings of the U-shaped heating line groups may also face one direction along the X direction, in this case, both the first part and the second part of the U-shaped heating line group extend along the X direction and the third part extends along the Y direction.

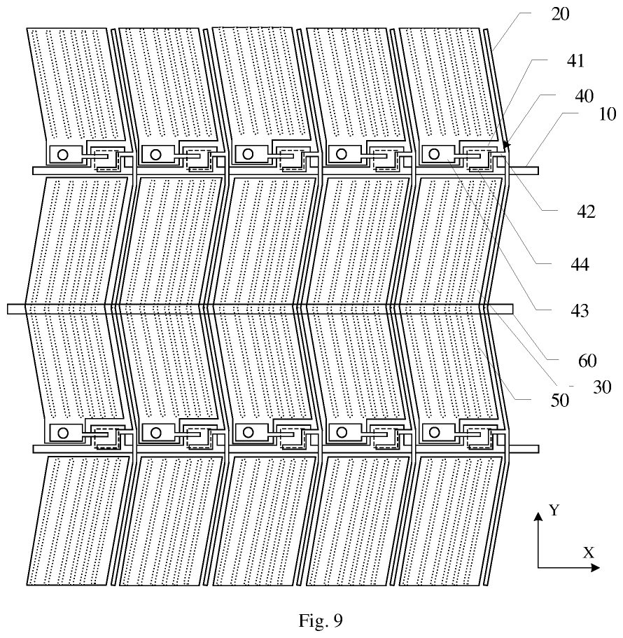

FIG. 8 is a schematic plan view of an array substrate according to some embodiments of the present disclosure. As illustrated by FIG. 8, that array substrate includes a base substrate (not shown in the figure) and a plurality of gate lines 10 formed on the base substrate, and the plurality of gate lines extend in the X direction. The array substrate further includes a plurality of data lines 20 located on the base substrate and extending in the Y direction. As illustrated by FIG. 8, the expression that the data lines extend along the Y direction does not refer to the case that each segment of one of the data lines strictly extends along the Y direction, but extends along the Y direction as a whole. Local segments of the one of the data lines may be inclined at a certain angle to the Y direction. In this embodiment, the X direction and the Y direction are perpendicular to each other, but the embodiments according to the present disclosure are not limited thereto, and the X direction and the Y direction may cross each other at a predetermined angle.

As illustrated by FIG. 8, the plurality of gate lines 10 and the plurality of data lines 20 are arranged to cross each other, thereby defining a plurality of sub-pixel regions. A pixel electrode 30 is provided in each of the plurality of sub-pixel regions. In FIG. 8, only a partial plan view of the array substrate is shown. For example, FIG. 8 only shows five complete pixel electrodes (sub-pixel regions) located in the middle, while only half of the pixel electrodes are shown at the upper side and the lower sideof the pixel electrodes in the middle row. For example, in each row of sub-pixel regions, a plurality of sub-pixel regions with different colors can be sequentially and repeatedly arranged, and a corresponding pixel electrode is arranged in each of the sub-pixel regions. It should be noted that the color of the liquid crystal display panel is realized by color filters in the color film layer. Therefore, there may be no difference in pixel electrodes of sub-pixels of different colors. Herein, they are numbered separately to explain the distribution of pixel electrodes corresponding to sub-pixels of different colors in the array substrate. For example, the pixel electrodes of different colors arranged sequentially and repeatedly in the X direction include a pixel electrode 31 of a red sub-pixel, a pixel electrode 32 of a green sub-pixel and a pixel electrode 33 of a blue sub-pixel. In the embodiment, each column of sub-pixels can be sub-pixels of the same color. The arrangement of the sub-pixels is only exemplary, and the array substrate according to the embodiment of the present disclosure can adopt any suitable arrangement.

As illustrated by FIG. 8, each of the sub-pixel regions includes a switching transistor 40. The switching transistor 40 includes a gate electrode 41, a source electrode 42, and a drain electrode 43. In addition, the switching transistor 40 also includes an active layer 44. The specific structure of the switching transistor is not described in detail herein, and it can adopt any suitable thin film transistor or other transistor. For example, in this embodiment, the gate electrode 41 is formed as a part protruding from one side of the gate line 10, and the source electrode 42 is formed as a part extending outward from one side of the data line 20. Therefore, the gate electrode 41 can be integrally formed with the gate line 10 and the source electrode 42 can be integrally formed with the data line 20, but the embodiment according to the present disclosure is not limited thereto. The drain electrode 43 of the switching transistor 40 may be electrically connected with the pixel electrode 30 to apply a data signal to the pixel electrode 30.

As illustrated by FIG. 8, the heating line 60 extending in the X direction is disposed adjacent to the gate line 10. For example, the adjacent arrangement here may be the case that a distance between an orthographic projection of the heating line 60 on the base substrate and an orthographic projection of the gate line 10 on the base substrate is less than 3 microns, and in some examples, the distance may be less than 4 microns, 5 microns or 6 microns. However, the embodiments of the present disclosure are not limited thereto.

As illustrated by FIG. 8, the heating line 60 overlaps the edges of the pixel electrodes 30. In addition, the array substrate may also include a common electrode arranged opposite to the pixel electrode, and the heating line 60 may also overlap the edge of the common electrode. For example, the pixel electrode or the common electrode is provided with slits (dotted line strip structure) as illustrated by FIG. 8, and the heating line 60 may overlap with the ends of the slits in the pixel electrode or the common electrode.

As illustrated by FIG. 8, each of the gate lines 40 may be correspondingly provided with a heating line. In this case, the number of the linear heating lines in the display region is equal to the number of the gate lines. However, the embodiments according to the present disclosure are not limited thereto, and according to the requirements for heating power, heating lines may be provided only at part of the gate lines. For example, a heating line can be provided every other gate line. In this case, the number of the linear heating lines in the display region is half of the number of the gate lines. It should be noted that the implementation shown in FIG. 8 is to explain the positional relationship between the heating lines and other components in the display region, which may be the heating lines in the heating line groups along the X direction in the aforementioned embodiment or the part where the heating lines in the U-shaped heating line groups in the aforementioned embodiment extend along the X direction.

FIG. 9 is a schematic plan view of an array substrate according to some embodiments of the present disclosure. The embodiment shown in FIG. 9 is different from the embodiment shown in FIG. 8 in that the positions of the heating lines 60 are different. As illustrated by FIG. 9, a plurality of slits 50 are provided in the pixel electrode 30. The plurality of slits 50 extend substantially in the Y direction and are arranged in the X direction. Each of the slits 50 is divided into a slit portion located at the upper side and a slit portion located at the lower side. The extending direction of the slit portion located at the upper side is different from that of the slit located at the lower side. Therefore, the slit portion located at the upper side forms a first slit group, and the slit portion located at the lower side forms a second slit group. Because of the existence of the slits, the direction of the electric field applied to the liquid crystal in the sub-pixel is different. Therefore, two domains are formed in the sub-pixel region, and a domain boundary line is formed between the first slit group and the second slit group. In the embodiment shown in FIG. 9, the heating line 60 overlaps with the middle of a plurality of pixel electrodes arranged in the first direction, so that the heating line 60 overlaps with the domain boundary lines corresponding to the plurality of pixel electrodes arranged in the first direction. Because a dark region of the display will be formed at the domain boundary line, it has little influence on the aperture ratio of the display panel. For example, the extending direction of the slit in the pixel electrode and the angle with the Y direction are both schematic, and the embodiment of the present disclosure can be provided arbitrarily according to actual requirements.

In the embodiment of FIG. 9, the case where the pixel electrode 30 including slits has been described as an example. However, the embodiments according to the present disclosure are not limited thereto. For example, each of the sub-pixels may include a common electrode corresponding to the pixel electrode. The pixel electrode and the common electrode may face each other to apply an electric field to the liquid crystal in the sub-pixel. The abovementioned slits may be provided in the pixel electrode, the common electrode, or both the pixel electrode and the common electrode. No matter whether the slits are arranged in the pixel electrode or the common electrode, the joint of the slit groups extending in different directions can form the domain boundary line, so that a heating line can also be arranged at this position with little influence on the aperture ratio, and the detailed descriptions will not be repeated herein.

In this embodiment, the middle of each row of sub-pixels arranged in the X direction corresponds to a heating line 60, however, the embodiments according to the present disclosure are not limited thereto, and more or less heating lines may be provided according to the requirements for heating power. Similarly, it should be noted that the implementation shown in FIG. 9 is to explain the positional relationship between the heating line and other components in the display region, which may be the heating line in the heating line group along the X direction in the aforementioned embodiment, or the part of the heating line in the U-shaped heating line group in the aforementioned embodiment extends along the X direction.

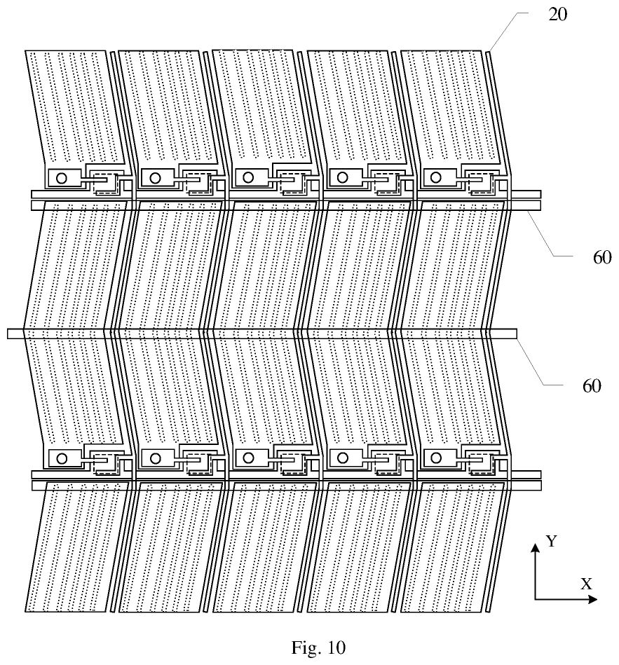

FIG. 10 is a schematic plan view of an array substrate according to some embodiments of the present disclosure. For the convenience of illustration, the same features as those in FIGS. 8 and 9 are not labeled. The difference from FIG. 8 and FIG. 9 is that the heating line 60 in the embodiment of FIG. 10 is provided at both the position adjacent to the gate line and the position overlapping with the domain boundary line. In this case, the number of linear heating lines may be equal to twice the number of rows of sub-pixels. However, embodiments according to the present disclosure are not limited thereto, and more or less heating lines may be provided according to the requirements for heating power. Similarly, it should be noted that the implementation shown in FIG. 10 is to explain the positional relationship between the heating line and other components in the display region, which may be the heating line in the heating line group along the X direction in the aforementioned embodiment or the part of the heating line in the U-shaped heating line group in the aforementioned embodiment extends along the X direction.

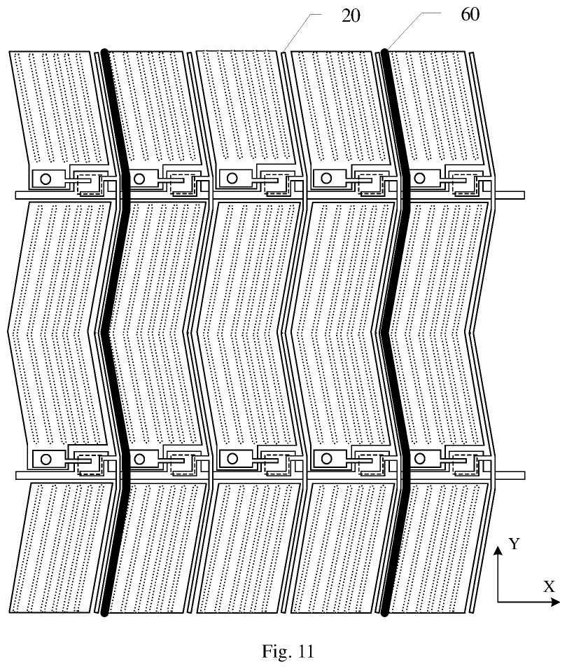

FIG. 11 is a schematic plan view of an array substrate according to some embodiments of the present disclosure. The basic structure of the array substrate is the same as that in FIG. 8 to FIG. 10, so some of the same features are not labeled. In this embodiment, the heating line 60 extends in the direction of the data line 20 and is disposed adjacent to the data line 20. For example, the adjacent arrangement here may be that the distance between the orthographic projection of the heating line 60 and the orthographic projection of the data line 20 on the base substrate is less than 3 microns, and in some examples, the distance may be less than 4 microns, 5 microns or 6 microns. In this embodiment, each column of pixels is correspondingly provided with a heating line. Each of the pixels includes three sub-pixels of a red sub-pixel, a green sub-pixel and a blue sub-pixel arranged along the X direction. That is, one heating line 60 is provided for every three columns of sub-pixels. However, the embodiment according to the present disclosure is not limited thereto, and more or less heating lines may be provided according to the requirements of heating power.

It should be noted that the implementation shown in FIG. 11 is to explain the positional relationship between the heating line and other components in the display region, which may be the heating line in the heating line group along the Y direction in the aforementioned embodiment or a part, extending in the Y direction, of the heating line in the U-shaped heating line group in the aforementioned embodiment.

FIG. 12 is a schematic plan view of an array substrate according to some embodiments of the present disclosure. The difference from FIG. 11 is that, in the embodiment of FIG. 12, each column of sub-pixels is provided with a heating line 60. Other parts are the same as those in FIG. 11, which can refer to the descriptions in FIG. 11 and will not be repeated herein. However, the embodiments according to the present disclosure are not limited thereto, and more or less heating lines may be provided according to the requirements of heating power. Similarly, it should be noted that the implementation shown in FIG. 12 is to explain the positional relationship between the heating line and other components in the display region, which may be the heating line in the heating line group in the Y direction in the aforementioned embodiment or a part, extending in the Y direction, of the heating line in the U-shaped heating line group in the aforementioned embodiment.

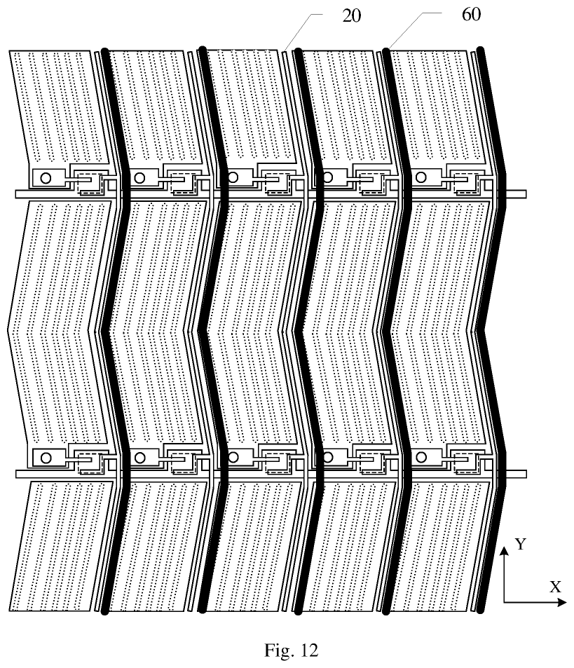

FIG. 13 is a schematic plan view of an array substrate according to some embodiments of the present disclosure, FIG. 13 shows a structure at a corner of a U-shaped heating line. As illustrated by FIG. 13, the corner of the U-shaped heating line includes a portion 61 extending in the X direction and a portion 62 extending in the Y direction. The portion 61 extending in the X direction is disposed adjacent to the gate line 10, similar to the heating line 60 disposed adjacent to the gate line 10 described above in FIG. 8. The portion 62 extending in the Y direction is disposed adjacent to the data line 20, similar to the heating line 60 disposed adjacent to the data line 20 described above in FIG. 12. The position where the portion 61 extending in the X direction crosses the portion 62 extending in the Y direction is called as the corner of the U-shaped line.

Although the case that the portion 61 extending in the X direction is arranged adjacent to the gate line and the portion 62 extending in the Y direction is arranged adjacent to the data line is described as an example in FIG. 13, the portion 61 extending in the X direction may also be arranged along the domain boundary line, that is, be overlapped with the middle of each row of sub-pixels. In this case, the corner of the U-shaped heating line is set at the intersection of the data line and the domain boundary line.

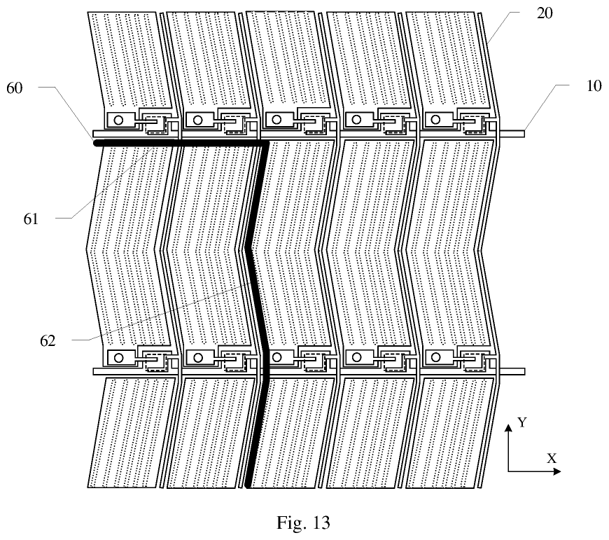

FIG. 14 is a schematic plan view of an array substrate according to some embodiments of the present disclosure, FIG. 14 shows a structure at a corner of a U-shaped heating line. Different from the implementation shown in FIG. 13, in the embodiment of FIG. 14, a recess portion 63 is provided at the position where the portion 62 of the heating line extending in the Y direction is adjacent to the switching transistor 40, and an opening of the recess portion 63 faces the switching transistor 40, so that the distance between the heating line and the active layer 44 of the switching transistor 40 is larger. Through the arrangement of the recess portion 63, the influence of the heating line on the operation performance of the switching transistor can be further avoided when the heating line is electrified and heated.

For example, the heating line 62 extending in the Y direction and the source electrode 42 are respectively arranged on two sides of the data line, where the opening of the recess portion 63 faces the switching transistor 40 connected to the data line, thus avoiding the influence of the heating line 62 on the operating performance of the switching transistor. It should be noted that the descriptions of the heating line 62 extending in the Y direction described herein is also applicable to the heating line 60 extending in the Y direction in the above embodiments. Therefore, in other embodiments, the heating line 60 extending in the Y direction can also be provided with a recess portion 63, which will not be described herein.

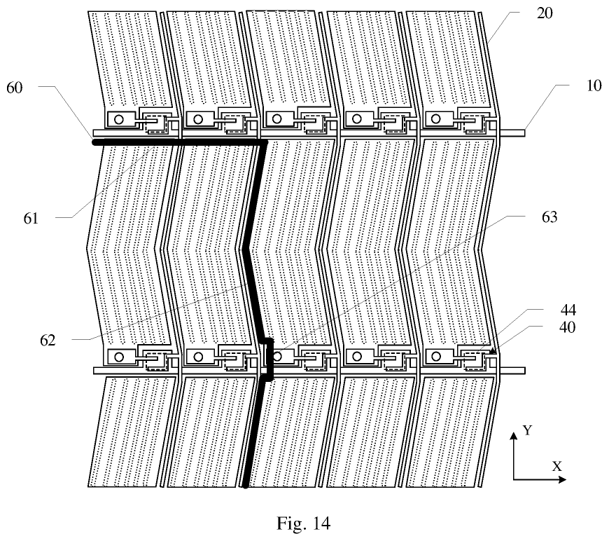

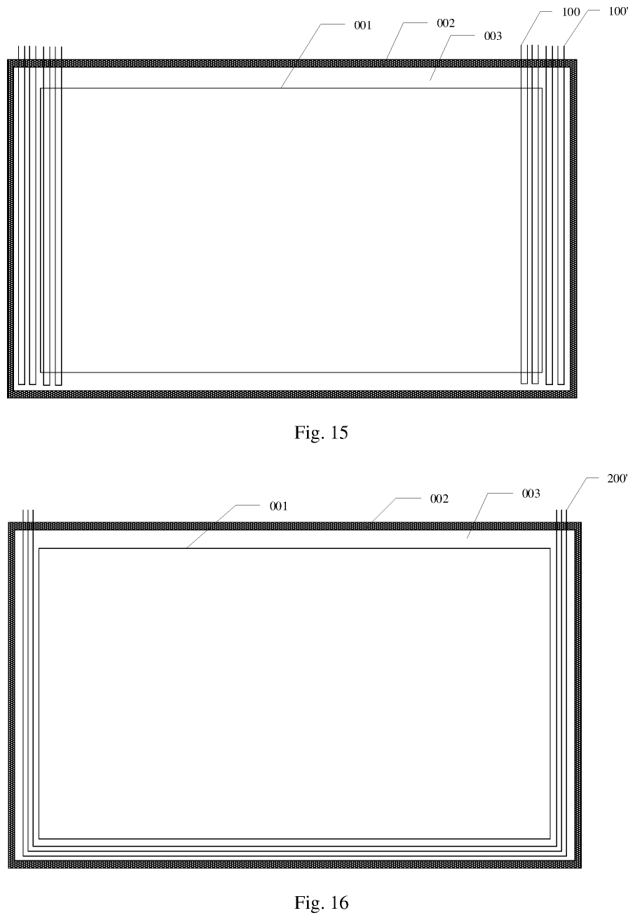

FIG. 15 is a schematic diagram of an arrangement mode of heating lines in an array substrate according to some embodiments of the present disclosure. As illustrated by FIG. 15, there is a peripheral region 003 between the display region (AA region) 001 and a region of the array substrate where the frame sealant 002 is to be provided. In this region, there will also be liquid crystal behind the display panel. Moreover, because this region is adjacent to the AA region, the change of its temperature has an impact on the AA region, especially a part of AA region adjacent to frame sealant 002. Therefore, in some embodiments, a heating line can also be provided in the AA region. In the embodiment of FIG. 15, in the case that the heating lines in the AA region are linear heating line groups, heating line groups 100′ similar to the heating line groups 100 in the AA region may be arranged on two sides of the AA region in the direction perpendicular to the extending direction of the heating line groups 100 in the AA region. For the convenience of illustration, only a simple U-shaped line is used in FIG. 15 to represent two heating line groups connected with each other. In addition, as illustrated by FIG. 15, for the part located under the AA region, the heating line group 100 can be extended to the position close to the frame sealant for heating the part of the peripheral region 003. While the part of the peripheral region 003 on the upper side of AA region is also heated by the heating line group 100 extending to this part.

It should be noted that the heating line group 100′ in the peripheral region 003 has a similar structure to the heating line group 100 in the AA region, and each of the heating line groups 100′ may also include a plurality of heating lines connected in parallel, but the heating line density in the heating line group 100′ and the heating line density in the heating line group 100 may be different. For example, the line density of the heating line group 100′ is greater than that of the heating line group 100. Due to the rapid heat dissipation in the peripheral region of the display panel, the heat dissipation in the peripheral region is more intense than that in the middle of AA region. Under the same design conditions, the peripheral temperature of AA region is lower than that in the center of the AA region. Therefore, in order to avoid serious temperature loss, the line density of the heating line group 100′ can be provided to be larger, so that the heating power is larger and the heat dissipation in the peripheral region can be compensated. For example, by changing the design of the heating line, higher thermal power is generated in the peripheral region. Through the calculation of the heating power and the heat dissipation environment, the line width and the line interval in the peripheral region are adjusted to realize the uniform design of the whole screen heating.

Furthermore, in some examples, each of the heating line groups 100′ in the peripheral region may have only one heating line.

FIG. 16 is a schematic diagram of an arrangement mode of heating lines in an array substrate according to some embodiments of the present disclosure. Different from FIG. 15, in this embodiment, a U-shaped heating line group 200′ is arranged in the peripheral region 003. The U-shaped heating line group 200′ may have a similar structure to the U-shaped heating line group 200 arranged in the AA region in FIG. 5. For example, each of the heating line groups 200′ may include a plurality of U-shaped heating lines whose two ends are respectively connected. The heating line density in the heating line group 200′ and the heating line density in the heating line group 200 may be different. For example, the line density of the heating line group 200′ is greater than that of the heating line group 200. Because the peripheral region of the display panel dissipates heat quickly, in order to avoid serious temperature loss, the line density of the heating line group 100′ can be provided to be larger, thus making the heating power larger.

Furthermore, in some examples, each of the heating line groups 200′ in the peripheral region 003 may have only one heating line.

It should be noted that FIG. 15 and FIG. 16 mainly illustrate the arrangement mode of the second heating lines in the peripheral region between AA region of the array substrate and the frame sealant. Whether the wiring mode of FIG. 15 or the wiring mode of FIG. 16 is adopted in the peripheral region of the array substrate according to the embodiment of the present disclosure, the wiring mode of the heating lines in the AA region of any of the above embodiments can be adopted as long as they are not overlapped upon being arranged.

In some examples, if the second heating line in the peripheral region between the AA region of the array substrate and the frame sealant adopts the arrangement mode of FIG. 15, the first heating line group and the second heating line group can be arranged in parallel and led out from the same side of the display region to the conductive terminals. If the second heating line in the peripheral region between the AA region of the array substrate and the frame sealant adopts the arrangement mode shown in FIG. 16, the U-shaped opening of the second heating line faces a region where the conductive terminal connected with the first heating line is arranged, so that the conductive terminal of the second heating line can be arranged on the same side of the display region as the conductive terminal of the first heating line. This layout can facilitate wiring and save space. For example, in the case that the second heating line in the peripheral region adopts the arrangement mode of FIG. 16 and the first heating line in the display region also adopts the arrangement mode of U-shaped heating line group, the U-shaped opening of the first heating line group and the U-shaped opening of the second heating line group have the same orientation.

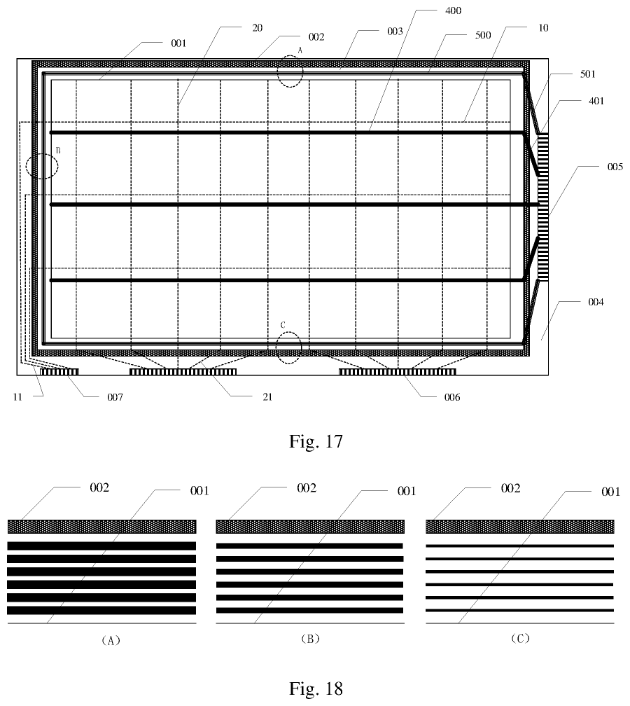

FIG. 17 is a schematic plan view of an array substrate according to some embodiments of the present disclosure. As illustrated by FIG. 17, the array substrate includes a display region (AA region) 001 and a region for setting a frame sealant 002. The region between the region for setting the frame sealant 002 and an edge of the array substrate is the first peripheral region 004, and the region between the region for setting the frame sealant 002 and the AA region is the second peripheral region 003. A flip-chip film 005 is disposed in a portion of the first peripheral region 004 located at the right side of the AA region. The flip-chip film is provided with conductive terminals for connecting with the heating lines. A source driving IC 006 and a gate driving IC 007 are provided in a portion of the first peripheral region 004 located at the lower side of the AA region. The gate line 10 extends in the X direction and is connected to the gate driving IC 007 through a gate lead-out line 11 located at the left side of the AA region. The data line 20 extends in the Y direction and is connected to the source driving IC through a data lead-out line 21 located at the lower side of the AA region. It can be seen from FIG. 17, it includes two source driving ICs. The above are the basic structures of the array substrate, which are only used to explain the arrangement mode of the heating lines, so any other suitable array substrate structure can be adopted for these basic structures. It should be noted that the positions where the gate driving IC and the source driving IC are arranged can also be replaced by gate driving conductive terminals and data line driving conductive terminals, while the gate driving IC and the source driving IC can be provided separately and connected with the corresponding gate driving conductive terminals and data line driving conductive terminals.

As illustrated by FIG. 17, on the array substrate, a first heating line 400 is arranged in the AA region, and a second heating line 500 is arranged in the second peripheral region 003. It should be noted that the first heating line 400 and the second heating line 500 are only schematic structures. For example, the first heating line 400 may adopt the heating line structure set in the AA region in any of the above embodiments, and the second heating line 500 may adopt the heating line structure set in the peripheral region (second peripheral region) 003 in any of the above embodiments. FIG. 17 is a diagram for explaining the connection mode of the first heating line 400 and the second heating line 500 with the conductive terminals in the flip-chip film 005 in the first peripheral region. As illustrated by FIG. 17, the first heating line 400 is connected to the conductive terminal of the flip-chip film 005 through a first fan-out line 501, and the second heating line 500 is connected to the conductive terminal of the flip-chip film 005 through a second fan-out line 401.

It should be noted that the line density of the second heating line 500 may be different at a side opposite to the side where the source driving IC is arranged, at a side adjacent to the side where the source driving IC is arranged (for example, the left side in the figure) and at the same side where the source driving IC is arranged. In order to explain the variation of line density in different regions, enlarged schematic diagrams at positions A, B and C in FIG. 17 are shown in FIG. 18, respectively.

FIG. 18 shows a partially enlarged schematic view at three positions of FIG. 17. As illustrated by FIG. 18, Fig. (A), Fig. (B) and Fig. (C) respectively show the distribution schematic diagrams of the second heating lines at three positions A, B and C in FIG. 17. At the position A, the line density is largest; at the position C, the line density is smallest. For example, the line density refers to a sum of heating line widths per unit length in a direction perpendicular to the extending direction of the heating line or the frame sealant. Because the width of the second peripheral region is approximately the same at each side of the display region. Therefore, in order to change the line density, the width of each heating line can be changed. The line density can be changed by changing the widths of the heating lines, and the number of the heating lines in the second peripheral regions on each side of the display region is equal, which is convenient for the layout of the second heating line. This mode of arranging the heating lines is set in consideration of the different temperatures of different sides of the display region. The side of the display region where the source driving IC or the gate driving IC is arranged will generate heat itself during the operation of the display panel, so a smaller line density can be provided in the second peripheral region herein; at the side opposite to the side where the source driving IC or the gate driving IC is arranged, because the source driving IC or the gate driving IC is the farthest and the temperature is lower, a larger line density can be arranged in the second peripheral region here. On the other hand, for the side adjacent to the side where the source driving IC or the gate driving IC is arranged, a middle line density can be provided. By arranging different line densities, the heating power of each part is different, so as to balance the temperature difference of each part in the peripheral region, and further to have a more balanced temperature distribution in the display region.

For example, the heating power of the heating line can be adjusted by the line width, a line interval, voltage or current applied to the heating line, etc. Therefore, the above various features of the heating line or the power supply connected with the heating line (for example, power supply through the FPC) can be adjusted to obtain the required heating power. In some examples, the heating power per unit area of the first heating line in the display region is the first heating power, the heating power per unit area of the second heating line in the second peripheral region on the lower side of the display region (the side where the driving IC is arranged) is the second heating power, the heating power per unit area of the second heating line in the second peripheral region on the left side of the display region is the third heating power, and the heating power per unit area of the second heating line in the upper side of the display region is the fourth heating power. The second heating power is greater than the first heating power, the third heating power is greater than or equal to the fourth heating power, and the fourth heating power is greater than or equal to the third heating power. In some examples, the second heating power is 2 to 10 times of the first heating power, the third heating power is 3 to 12 times of the first heating power, and the fourth heating power is 4 to 14 times of the first heating power. In other examples, the second heating power is 3 to 5 times that of the first heating power, the third heating power is 4 to 6 times that of the first heating power, and the fourth heating power is 5 to 8 times that of the first heating power.

Therefore, on the whole, the heating power per unit area in the second peripheral region can be greater than that in the display region to make up for the temperature drop in the peripheral region caused by heat dissipation.

For example, the above-mentioned comparison of the heating power can also be the relationship of heating power obtained under the condition of setting power supply parameters (for example, setting the voltage applied to the heating line in unit width and unit length), but the embodiments according to the present disclosure are not limited thereto.

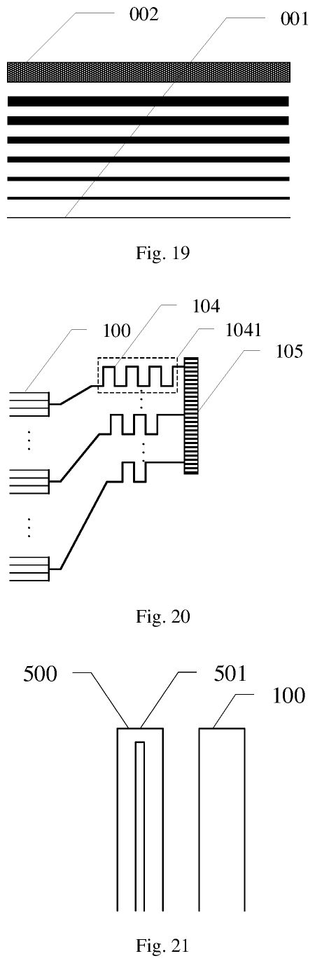

FIG. 19 shows another arrangement mode of heating lines in the second peripheral region of the array substrate. The heating line distribution in FIG. 19 is an exemplary line density change mode of the second peripheral region. Because the heat dissipation at the position closer to the edge of the array substrate is more obvious, the temperature at the region closer to the outside is lower. It can be seen from FIG. 19, the width of the heating line gradually increases along the direction from the display region to the frame sealant. By this way of line density change, the temperature in the peripheral region can be made more even.

FIG. 20 is a schematic plan diagram of fan-out lines connecting heating lines and conductive terminals. As illustrated by FIG. 20, the heating line group 100 is connected to the conductive terminal 105 of the flip-chip film through a fan-out line 104. According to the distance between the heating line group 100 and the conductive terminal 105 of the flip-chip film to be connected, the fan-out line 104 may be provided with a bending structure 1041. As illustrated by FIG. 20, the bending structure 1041 may be a square wave bending structure, but the present disclosure is not limited thereto. For example, the bending structure 1041 may also have other bending shapes. The uppermost heating line group 100 shown in the figure is closest to the conductive terminal to be connected, so the length of the bending structure 1041 in the fan-out line 104 is longest. However, the lowest heating line group 100 in the figure is farthest from the conductive terminal to be connected, so the length of the bending structure 1041 in the corresponding fan-out line 104 is shortest. By arranging bending structures with different lengths in the fan-out line, the total length of the fan-out line corresponding to the heating line groups at different positions can be adjusted to be approximately the same, thus avoiding the problem of uneven resistance of different heating line groups and the fan-out line connection structures.

FIG. 21 shows a schematic diagram of a dummy heating line and a temperature detection line in an array substrate according to some embodiments of the present disclosure. As illustrated by FIG. 21, in the case that the first heating line 100 in the display region adopts a linear heating line, a U-shaped dummy heating line 500 can be provided at the position outside the display region adjacent to the first heating line 100 in the display region, that is, the dummy heating line 500 is provided at a side of the display region and between the second heating line and the display region. For example, a temperature detection line 501 may be disposed inside the U-shaped dummy heating line.

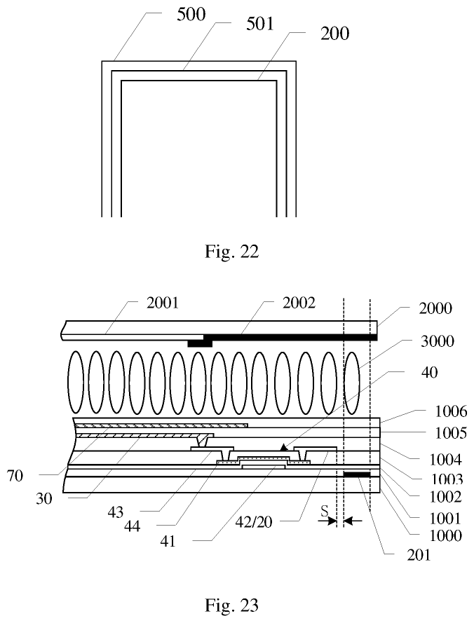

FIG. 22 shows a schematic diagram of a dummy heating line and a temperature detection line in an array substrate according to some embodiments of the present disclosure. As illustrated by FIG. 22, in the case that the first heating line 200 in the display region adopts a U-shaped heating line, U-shaped lines around multiple sides of the display region can be formed outside the display region as the dummy heating lines 500. In this case, the dummy heating line 500 is arranged at a side of the display region and between the second heating line and the display region. For example, the temperature detection line 501 may be arranged between the U-shaped line and the display region.

FIG. 23 illustrates a partial cross-sectional view of a display panel according to some embodiments of the present disclosure. As illustrated by FIG. 23, the display panel includes an array substrate according to any one of the above embodiments. FIG. 23 shows a partial cross-sectional schematic diagram of the array substrate, mainly showing the positions where heating lines are arranged adjacent to the switching transistors of the array substrate.

As illustrated by FIG. 23, the array substrate includes a first base substrate 1000, a heating line 201 arranged on the first base substrate, a first dielectric layer 1001 arranged on the heating line 201, a gate electrode 41 arranged on the first dielectric layer 1001, a gate insulating layer 1002 arranged on the gate electrode 41, an active layer 44 arranged on the gate insulating layer 1002, and a second dielectric layer 1004 arranged on the active layer 44. A source electrode 42, a data line 20 and a drain electrode 43 arranged on the second dielectric layer 1004. Because the source electrode 42 may be a part protruding from the data line 43, the source electrode 42 and the data line are viewed as an integral structure in the drawing. The array substrate also includes a third dielectric layer 1004 disposed on the source electrode 42 and the drain electrodes 43, a pixel electrode 30 disposed on the third dielectric layer 1004, a fourth dielectric layer 1004 disposed on the pixel electrode 30, and a common electrode 70 disposed on the fourth dielectric layer 1004 and a fifth dielectric layer 1006 disposed on the common electrode 70. For example, the fifth dielectric layer 1006 can also be used for an alignment layer in which a liquid crystal layer is aligned. It should be noted that this is only an example of the cross-sectional structure of the array substrate, and the array substrate according to the embodiment of the present disclosure is not limited thereto, so it can adopt any other suitable cross-sectional structure. For example, the order of the pixel electrode and the common electrode can be replaced, or the pixel electrode and the common electrode can be made on the same layer. A bottom gate transistor is shown in FIG. 23, and a top gate transistor can also be used.

The display panel further includes a color film substrate arranged opposite to the array substrate. The color film substrate includes a second base substrate 2000, a color filter 2001 and a black matrix 2002 arranged on the second base substrate 2000. For example, the color filter 2001 is a component for color display, and the light passing through the liquid crystal layer passes through the color filter 2001 to form color light. For example, the color filter 2001 may be a red color filter, a green color filter, a blue color filter and the like. The color filters 2001 are arranged corresponding to the pixel electrodes 30 on the array substrate, so that the corresponding sub-pixels form sub-pixels of corresponding colors. A black matrix 2002 is arranged between a plurality of color filters 2001, and the black matrix 2002 is used for shielding the opaque part on the array substrate and prevent crosstalk of light from adjacent pixels.

The display panel further includes a liquid crystal layer 3000 disposed between the array substrate and the color film substrate. In addition, a frame sealant is also arranged between the array substrate and the color film substrate in the display panel, and the specific setting region of the frame sealant can refer to the region where the frame sealant 02 is arranged in the above embodiment, so as to form a liquid crystal cell for containing liquid crystal by combining the array substrate and the color film substrate. The liquid crystal layer 3000 is arranged in the region surrounded by the frame sealant between the array substrate and the color film substrate.

FIG. 23 is a cross-sectional view of an exemplary structure in which a heating line extends in the direction of a data line. For example, the heating line 201 is disposed adjacent to the data line 20 with an interval S therebetween. For example, as mentioned above, the interval S may be less than 3 microns, or less than 6 microns. For example, the heating line 201 is blocked by the black matrix 2002, and an orthographic projection of the heating line on the base substrate 1000 falls within an orthographic projection of the black matrix 2002 on the base substrate 1000. Therefore, the arrangement of the heating line 201 basically does not affect the aperture ratio of the display panel.

Although FIG. 23 only takes the heating line 201 arranged along the data line as an example, the heating line 101 arranged along the gate line in the above embodiment can also have a similar structure, that is, the orthographic projection of the heating line 101 arranged along the gate line on the base substrate 1000 falls within the orthographic projection of the black matrix 2002 on the base substrate 1000. Therefore, the arrangement of the heating line 101 basically does not affect the aperture ratio of the display panel.

In FIG. 23, it is only described that the heating line is located in a lower layer of the gate line. However, the heating line of the array substrate according to the embodiment of the present disclosure can be formed in other layers, for example, it can also be formed in the upper layer of the source electrode and the drain electrode or in the same layer as other conductive layers. However, by forming the heating line in a different layer from the gate line and the data line, the interference of the heating line to the gate line and the data line during heating can be reduced. In addition, in the case that the heating line and the gate line or the data line are in different layers, the heating line arranged along the gate line and the heating line arranged along the data line may also at least partially overlap with the gate line and the data line respectively (in the direction perpendicular to the base substrate). For example, in a plan view, there may be no gap between the corresponding heating line and the gate line, or between the corresponding heating line and the data line. In this example, the width of the black matrix covering the gate line or the data line can be made smaller, so that the aperture ratio of the array substrate or the display panel can be improved.

Furthermore, in some examples, the material of the heating line may be metal. For example, aluminum (Al), copper (Cu), molybdenum (Mo) and the like. In addition, the material of the heating line may be the same as that of the gate line or the data line.

In addition, the display panel may also include a flexible printed circuit board connected to the conductive terminals on the flip-chip film. Flexible printed circuit board can refer to the descriptions of the connection relationship between the conductive terminal and the flexible printed circuit board described in the above embodiments, which will not be repeated herein.

For other structures and features of the array substrate in the display panel, please refer to the above-mentioned embodiment of the array substrate, which will not be repeated herein. Because the display panel according to the embodiment of the present disclosure adopts the array substrate mentioned above, a plurality of heating lines in each of the heating line groups can share one or more conductive terminals, thereby reducing the number of the conductive terminals for applying power to the heating lines.

Therefore, the display panel according to the embodiment of the present disclosure can also solve the problems that the length of the flip-chip film is too long, the cost is increased, the bending stress is increased, and there is a risk of light leakage.

According to the embodiment of the present disclosure, a method for manufacturing an array substrate is also provided, which comprises: forming a gate electrode layer on a base substrate, the gate electrode layer comprises a gate electrode and a gate line; forming a gate insulating layer on the gate electrode layer; forming an active layer on the gate insulating layer, the active layer can be any suitable semiconductor material layer, and forming a source-drain electrode layer on the active layer, the source-drain electrode layer can include a source electrode, a drain electrode and a data line; forming a first passivation layer on the source-drain electrode layer; forming a heating line layer on the first passivation layer; forming a second passivation layer on the heating line layer; and forming a first transparent conductive layer on the second passivation layer, which may include a common electrode. For example, the first transparent conductive layer may be an indium tin oxide (ITO) layer. The method further includes: forming a third passivation layer on the first transparent conductive layer; and forming a second transparent conductive layer on the third passivation layer, which may include a pixel electrode. For example, the second transparent conductive layer may be an indium tin oxide (ITO) layer. It should be noted that the process steps here are only exemplary. For example, in the manufacturing method, a heating line is formed above the source-drain electrode layer, which is different from the position of the heating line in the embodiment described in FIG. 23, and other structural layers are also different from the embodiment described in FIG. 23.

For example, in the case of FIG. 23, the heating line may be formed on the base substrate firstly, and then the structures such as the gate lines, the data lines and the transparent conductive layers may be formed. For example, in the case where the heating line is formed on the same layer as the gate lines and the data lines, the step of separately forming the heating line layer can be omitted.

The following points need to be explained:
(1) The drawings of the embodiment of the present disclosure only relate to the structure related to the embodiment of the present disclosure, and other structures can refer to the general design.
(2) In the case of no conflict, the embodiments of the present disclosure and the features in the embodiments can be combined with each other to obtain a new embodiment.

The above is only the specific embodiments of the present disclosure, but the protection scope of the present disclosure is not limited thereto. Any person skilled in the art can easily think of changes or substitutions within the technical scope disclosed in the present disclosure, and they should be included in the protection scope of the present disclosure. Therefore, the scope of protection of the present disclosure should be based on the scope of protection of the claims.

1. An array substrate, comprising a display region and a first peripheral region surrounding the display region, wherein the array substrate comprises:
a base substrate;
a plurality of gate lines, located on the base substrate and extending along a first direction;
a plurality of data lines, located on the base substrate and extending along a second direction, wherein the second direction and the first direction cross each other;
a plurality of pixel electrodes, arranged in an array along the first direction and the second direction respectively;
a plurality of heating line groups, at least partially arranged in the display region, wherein each of the plurality of heating line groups comprises a plurality of first heating lines arranged at intervals, and the plurality of first heating lines in each of the plurality of heating line groups are connected with each other through connection lines at two ends of the each of the plurality of heating line groups, respectively.

2. The array substrate according to claim 1, wherein the array substrate further comprises an annular region configured to arrange a frame sealant, the annular region is located between the first peripheral region and the display region, and the array substrate further comprises a second peripheral region located between the annular region and the display region.

3. The array substrate according to claim 2, wherein the plurality of heating line groups extend in a third direction and are arranged along a fourth direction crossing the third direction, one of the third direction and the fourth direction is parallel to the first direction, and the other of the third direction and the fourth direction is parallel to the second direction.

4. The array substrate according to claim 3, wherein the connection lines at first ends of every two adjacent ones of the plurality of heating line groups are electrically connected with each other, and the connection lines at second ends of every two adjacent ones of the plurality of heating line groups, which are electrically connected with each other, are respectively connected to different conductive terminals located in the first peripheral region.

5. The array substrate according to claim 3, wherein ends of the plurality of heating line groups extend to the second peripheral region.

6. The array substrate according to claim 4, wherein the connection lines at the second ends of the plurality of heating line groups are connected to the conductive terminals through fan-out lines.

7. The array substrate according to claim 6, wherein a width of each of the fan-out lines is greater than a width of each of first heating lines in the plurality of heating line groups.

8. The array substrate according to claim 4, wherein each of the heating line groups is connected with a plurality of conductive terminals, and a number of the first heating lines in each of the plurality of heating line groups is greater than a number of the conductive terminals connected with the each of the plurality of heating line groups.

9. The array substrate according to claim 3, wherein the third direction is parallel to the first direction, and multiple first heating lines in the plurality of heating line groups are arranged in at least one of following two positions:
adjacent to corresponding gate lines, and a distance between an orthographic projection of a first heating line on the base substrate and an orthographic projection of a corresponding gate line on the base substrate is less than 6 microns;
overlapping with middle parts of the plurality of pixel electrodes arranged in the first direction.

10. The array substrate according to claim 9, further comprising common electrodes corresponding to the plurality of pixel electrodes, wherein pixel electrode and common electrode, which correspond to each other, are configured to apply an electric field, at least one of the pixel electrode and the common electrode, which correspond to each other, is provided with two groups of slits extending in different directions from each other to form a domain boundary line extending in the first direction at a joint of the two groups of slits,
at least part of the first heating lines is overlapped with the middle parts of the plurality of pixel electrodes arranged in the first direction, so that the first heating lines overlap with domain boundary lines corresponding to the plurality of pixel electrodes arranged in the first direction.

11-16. (canceled)

17. The array substrate according to claim 2, wherein each of the plurality of heating line groups is U-shaped as a whole, and lengths of the plurality of heating line groups are different, so that the U-shaped heating line groups are sequentially nested.

18. The array substrate according to claim 17, wherein each first heating line in the plurality of heating line groups is U-shaped, and lengths of the first heating lines are different, so that the U-shaped first heating lines are sequentially nested, and an interval between adjacent first heating lines in each of the plurality of heating line groups is approximately the same as an interval between adjacent heating line groups.

19. The array substrate according to claim 17, wherein each of the plurality of heating line groups comprises a first part and a second part located on two sides of a center line of the display region, and extending directions of the center line, the first part and the second part are parallel to each other, and each of the plurality of heating line groups comprises a connection part connecting the first part and the second part, and an extending direction of the connection part is perpendicular to the extending direction of the center line.

20. The array substrate according to claim 19, wherein the connection lines at first ends and second ends of the plurality of heating line groups are respectively electrically connected to different conductive terminals located in the first peripheral region.

21. The array substrate according to claim 19, wherein the connection lines at first ends of the plurality of heating line groups are respectively electrically connected to different conductive terminals in the first peripheral region, and the connection lines at second ends of every two heating line groups in the plurality of heating line groups are electrically connected with each other.

22. The array substrate according to claim 21, wherein second parts of the plurality of heating line groups are arranged in sequence along a direction perpendicular to the extending direction of the center line, the second parts are located on two sides of a dividing line parallel to the center line, and the second parts located on one side of the dividing line are arranged in one-to-one correspondence with the second parts located on the other side of the dividing line, and the second parts located on two sides of the dividing line and corresponding to each other are symmetrical with respect to the dividing line in the direction perpendicular to the center line, and the connection lines of the corresponding second parts are electrically connected with each other.

23. The array substrate according to claim 2, further comprising a plurality of second heating lines, wherein the second heating lines are sequentially arranged from the display region toward the first peripheral region.

24. The array substrate according to claim 23, wherein a line density of the plurality of second heating lines at a position close to the display region is smaller than a line density of the second heating lines at a position close to the first peripheral region.

25. The array substrate according to claim 23, wherein a line density of the plurality of second heating lines located in the second peripheral region is greater than a line density of the first heating lines located in the display region.

26. (canceled)

27. The array substrate according to claim 4, further comprising a plurality of second heating lines, wherein the second heating lines are located in the second peripheral region and arranged in sequence from the display region toward the first peripheral region, each of the second heating lines is U-shaped to surround a plurality of lateral edges of the display region, and a U-shaped opening of each of the second heating lines faces a region where the conductive terminals are arranged.

28-51. (canceled)
